(19) United States
(12) Patent Application Publication
(10) Pub. No.: US 2009/0108418 A1
(43) Pub. Date: Apr. 30, 2009

(54) Non-leaded semiconductor package structure

(76) Inventors: Wa-Hua Wu, Chu-Tung (TW); Szu-Chuan Pang, Chu-Tung (TW); Chung-Yang Wu, Chu-Tung (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/976,775

(22) Filed: Oct. 29, 2007

(51) Int. Cl. H01L 23/495

(52) U.S. Cl. 257/666; 257/E23.031

(57) ABSTRACT

A non-leaded semiconductor package structure is proposed, in which the structure of a lead frame is improved to let the lower surface of a die paddle of the lead frame be used to carry a die and the upper surface thereof be exposed out of the package structure. Moreover, a plurality of leads of the lead frame is located at the periphery of the lower surface of the die paddle. Each lead has an inner lead and an outer lead, and the outer lead is exposed out of the package structure. The package structure thus formed has a good heat-radiating effect and a reduced chance of leakage current.

### BACKGROUND OF THE INVENTION

1. Field of the Invention

The present invention relates to a semiconductor package structure and, more particularly, to a non-leaded semiconductor package structure.

2. Description of Related Art

Semiconductor packaging technology is used to package semiconductor dies to protect them from damage. With continual progress of semiconductor manufacturing techniques, the density of ICs increases. Therefore, how to let the packaged die structure have stable electric characteristics, a fast execution speed, a good heat-radiating effect, and a small package size is a major research topic in the field of packaging technology.

Quad flat non-leaded (QFN) packaging technique is a common package configuration. As shown in FIG. 1, a prior art QFN semiconductor package structure 10 comprises a lead frame, which has a die paddle 12 to carry a die 14. The lead frame also has a plurality of leads 16 at the periphery of the die paddle 12. Electrodes 17 on the die 14 and the leads 16 are electrically connected together by means of wire bonding. An encapsulant 18 is filled between the die 14, the die paddle 12 and the leads 16 through a mold process. Bottom faces 16a of the leads 16 and the bottom faces 18a of the encapsulant 18 are coplanar. That is, the bottom faces 16a of the leads 16 are not encapsulated by the encapsulant 18. Moreover, in order to prevent the bottom faces 16a of the leads 16 from oxidation and deterioration of wettability, electroplate coatings 29 are disposed on the bottom faces 16a of the leads 16. Therefore, because the formed QFN structure 10 has no leads protruding out of the package structure, the size of the package structure can be further reduced. However, this QFN semiconductor package structure 10 has a bad heat-radiating effect.

As shown in FIG. 2, another prior art QFN semiconductor package structure 22 comprises a lead frame, which includes a die paddle 24 and a plurality of leads 26. The structure of the leads 26 differ from that of the above leads 16. Each of the leads 26 has two end portions 261 and 262. The surfaces 261a and 262a of the two end portions 261 and 262 are not encapsulate by a encapsulant 28 but are exposed out of the front surface and back surface of the package structure, respectively, and are then covered by electroplate coatings 30. Moreover, the die paddle 24 has an upper surface 24a and a lower surface 24b. The upper surface 24a is exposed out of the front surface of the package structure, while the lower surface 24b is used to fix a die 32. Electrodes 33 of the die 32 are electrically connected with the end portions 261 of the leads 26 by means of wire bonding. Because the upper surface 24a of the die paddle 24 of this QFN package structure 22 is exposed out of the front surface of the package structure, a better heat-radiating effect is achieved. However, because there are leads exposed out of both the front and back surfaces of the package structure, current leakage may easily arise to cause electric breakdown.

Accordingly, the present invention aims to provide a non-leaded semiconductor package structure to solve the above problems in the prior art.

### SUMMARY OF THE INVENTION

An object of the present invention is to provide a non-leaded semiconductor package structure, in which the structure of a lead frame is improved to let the package structure have a good heat-radiating effect and to reduce the generation of leakage current. The improved lead frame has inner and outer leads. Only the outer leads are exposed out of the back surface of the package structure, while the inner leads are encapsulated by a encapsulant. Moreover, a die paddle of the lead frame is located at the upper portion of the inside of the formed package structure so that the upper surface of the die paddle can be exposed out of the front surface of the package structure. The lower surface of the die paddle is used to carry a die, and is encapsulated by the encapsulant.

To achieve the above object, the present invention provides a non-leaded semiconductor package structure, which comprises a lead frame, a die, and a encapsulant. The lead frame includes at least a die paddle with an upper surface and a lower surface and a plurality of leads located at the periphery of the lower surface of the die paddle. Each of the leads has an inner lead and an outer lead connected to the inner lead. The die is located on the lower surface of the die paddle and electrically connected to the inner leads of the leads. The encapsulant encapsulates the die, the inner leads and part of the die paddle with the upper surface of the die paddle and the outer leads exposed.

### BRIEF DESCRIPTION OF THE DRAWINGS

The various objects and advantages of the present invention will be more readily understood from the following detailed description when read in conjunction with the appended drawing, in which:

FIG. 1 is a cross-sectional view of a quad flat non-leaded semiconductor package structure in the prior art;

FIG. 2 is a cross-sectional view of another quad flat non-leaded semiconductor package structure in the prior art;

FIG. 3 is a cross-sectional view of a non-leaded semiconductor package structure of the present invention;

FIG. 4 is a cross-sectional view of a lead frame of the present invention; and

FIGS. 5A to 5F show the steps of manufacturing the non-leaded semiconductor package structure of the present invention.

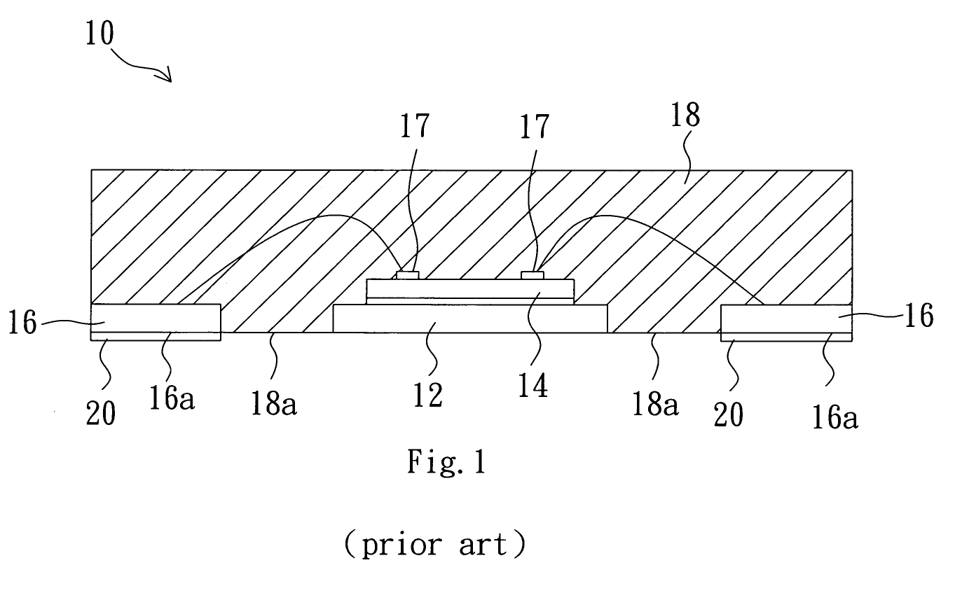

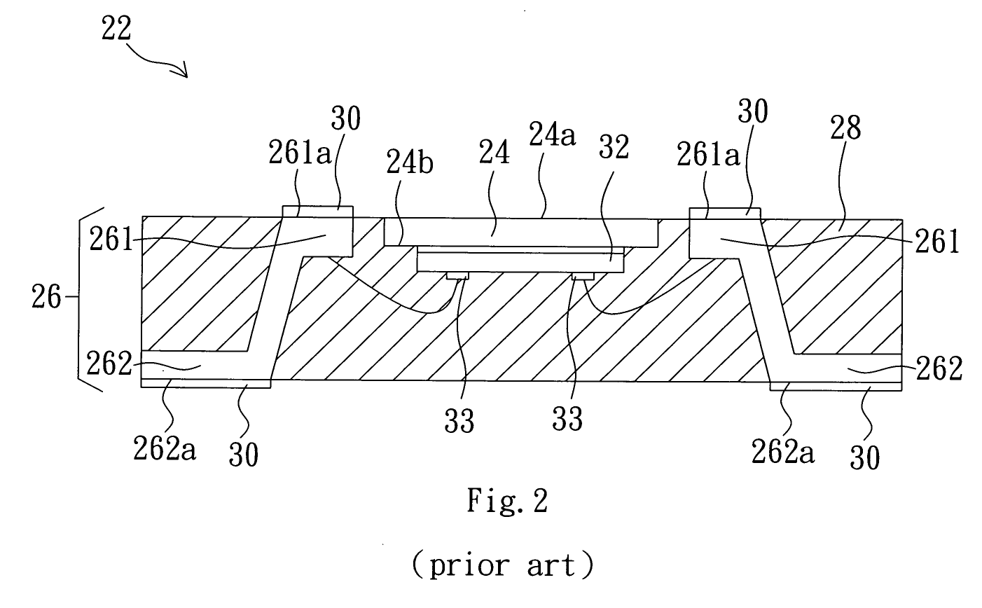

### DETAILED DESCRIPTION OF THE PREFERRED EMBODIMENTS

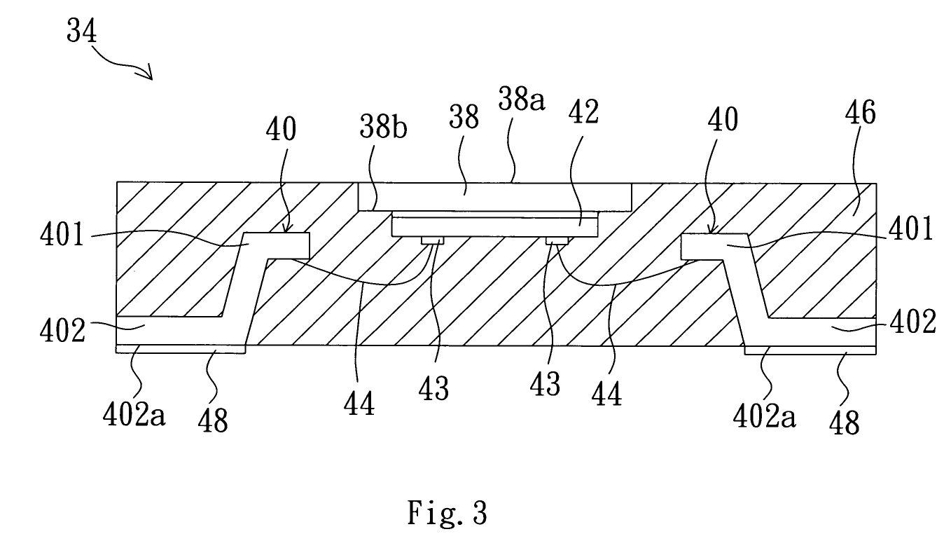

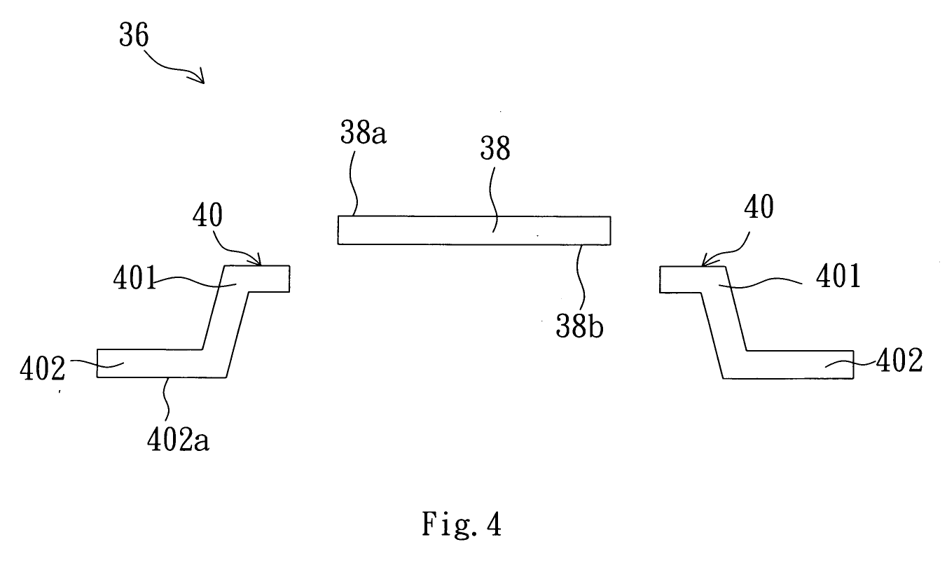

As shown in FIGS. 3 and 4, a non-leaded semiconductor package structure 34 of the present invention comprises a lead frame 36, a die 42 and an encapsulant 46. The lead frame 36 includes a die paddle 38 and a plurality of leads 40. The die paddle 38 has an upper surface 38a and a lower surface 38b opposed to each other. The leads 40 are located at the periphery of the lower surface 38b of the die paddle 38. Each of the leads 40 has an inner lead 401 and an outer lead 402 that are connected together. The die 42 is fixed on the lower surface 38b of the die paddle 38. Electrodes 43 on the die 42 are electrically connected to the inner leads 401 of the leads 40 via bonding wires 44. The encapsulant 46 made of plastic material is used to encapsulate the inner leads 401, the die 42 and part of the die paddle 38 with the upper surface 38a of the die paddle 38 and the bottom faces 402a of the outer leads 402 exposed. Moreover, a plurality of electroplate coatings 48 is disposed on the exposed bottom faces 402a of the outer leads 402 to prevent the bottom faces 402a of the outer leads 402 from oxidation and deterioration of wettability. An identification mark can be printed on the exposed upper surface 38a of the die paddle 38. The identification mark can be selected among character, numeral, symbol, or code.

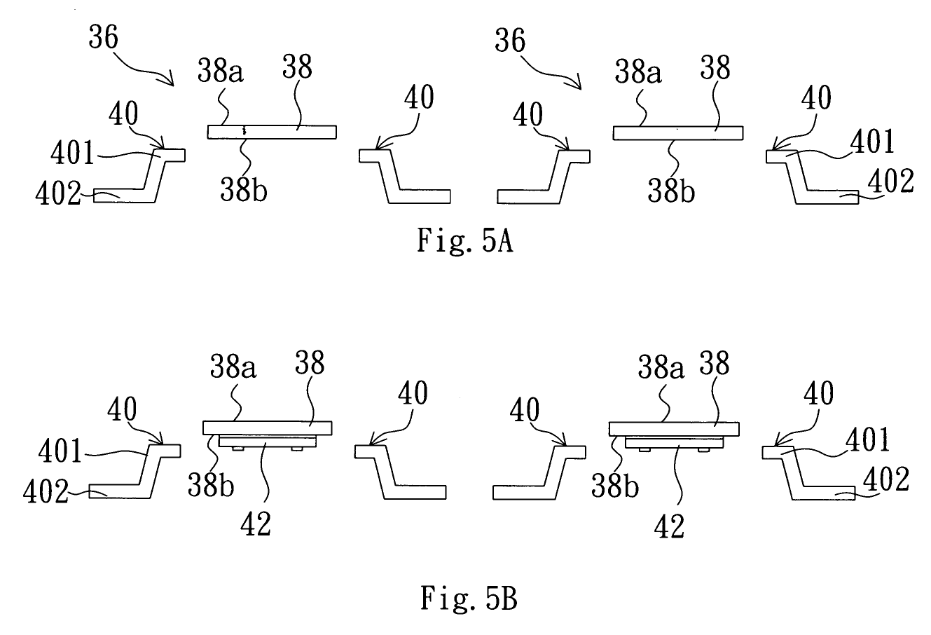

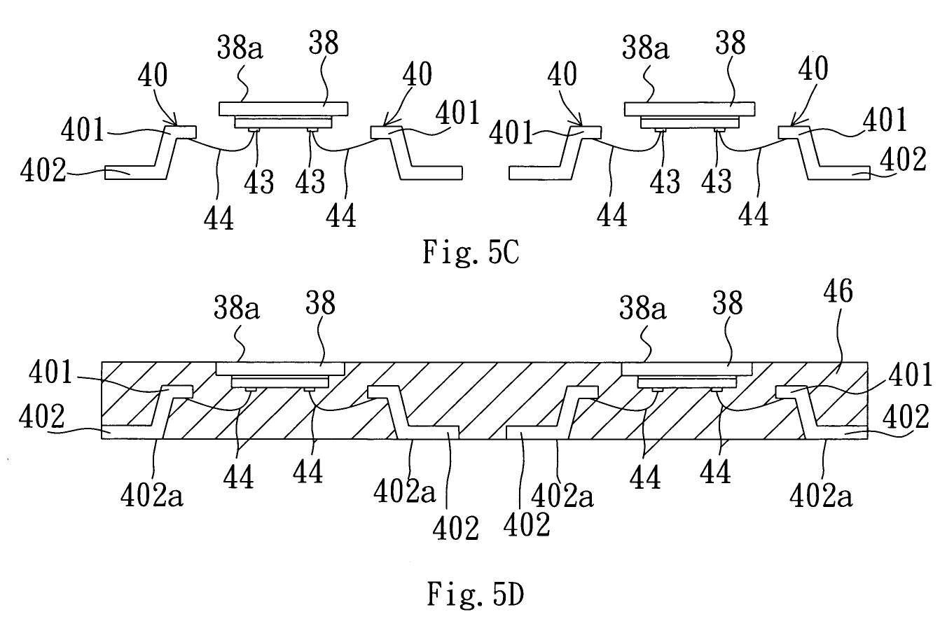

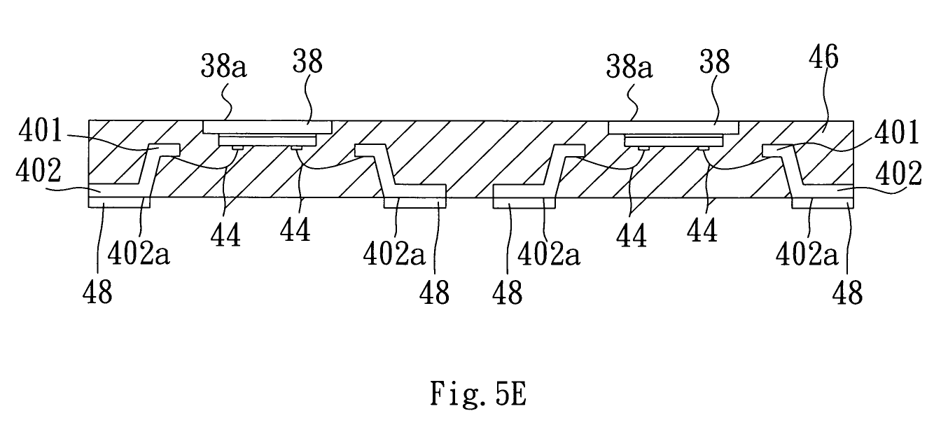

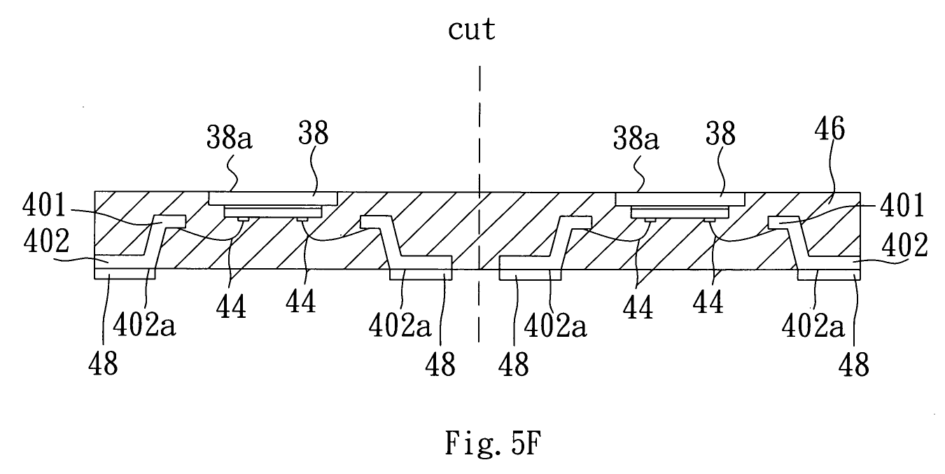

FIGS. 5A to 5F show the steps of manufacturing the non-leaded semiconductor package structure of the present invention. As shown in FIG. 5A, a plurality of lead frames 36 is provided. A die placement step is then performed. That is, the chip 42 is disposed on the lower surface 38b of the die paddle 38, as shown in FIG. 5B. Next, wire bonding is carried out to electrically connect the electrodes 43 on the die 42 and the inner leads 401 together, as shown in FIG. 5C. As shown in FIG. 5D, the encapsulant 46 is formed through a mold process to expose the upper surface 38a of the die paddle 38 and the bottom faces 402a of the outer leads 402. Subsequently, as shown in FIG. 5E, the electroplate coatings 48 are formed on the exposed bottom faces 402a of the outer leads 402, and the identification mark selected among character, numeral, symbol, pattern or code is printed on the upper surface 38a of the die paddle 38. Finally, as shown in FIG. 5F, a cutting procedure is performed to form a plurality of non-leaded semiconductor package structures 34.

To sum up, the present invention discloses a non-leaded semiconductor package structure, in which the upper surface of the die paddle is exposed out of the front surface of the package structure and the outer leads are exposed out of the back surface of the package structure. The proposed non-leaded semiconductor package structure not only has a good heat-radiating effect, but also the advantage of small size of the conventional QFN package structure. Moreover, the problem of current leakage in the prior art due to exposed leads on the front and back surfaces of the package structure is also solved.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

I claim:

1. A non-leaded semiconductor package structure comprising:
a lead frame including at least a die paddle with an upper surface and a lower surface, a plurality of leads being located at a periphery of said lower surface of said die paddle, each said lead having an inner lead and an outer lead connected to said inner lead;
a die located on said lower surface of said die paddle and electrically connected to said inner leads of said leads; and
an encapsulant encapsulating said die, said inner leads and part of said die paddle with said upper surface of said die paddle and said outer leads exposed.

2. The non-leaded semiconductor package structure as claimed in claim 1, wherein said die and said inner leads are electrically connected together by means of wire bonding.

3. The non-leaded semiconductor package structure as claimed in claim 1 further comprising a plurality of electroplate coatings located at exposed positions of said outer leads.

4. The non-leaded semiconductor package structure as claimed in claim 1, wherein an identification mark is printed on said upper surface of said die paddle.

5. The non-leaded semiconductor package structure as claimed in claim 4, wherein said identification mark is selected among character, numeral, symbol, or code.

6. The non-leaded semiconductor package structure as claimed in claim 1, wherein said encapsulant is made of plastic material.
